(19) United States
(12) Patent Application Publication
(10) Pub. No.: US 2025/0232826 A1
(43) Pub. Date: Jul. 17, 2025

(54) MULTI-REFERENCE-VOLTAGE SAMPLED-BANDGAP SYSTEM

(71) Applicant: QUALCOMM Incorporated, San Diego, CA (US)

(72) Inventor: Christian CAMPORESE, Cambridge (GB)

(21) Appl. No.: 18/412,114

(22) Filed: Jan. 12, 2024

(51) Int. Cl. G11C 27/02; G05F 1/46; H03F 3/45

(52) U.S. Cl. CPC G11C 27/026; G05F 1/468; H03F 3/45197

(57) ABSTRACT

A multi-reference-voltage sampled-bandgap system is provided in which a sample-and-hold circuit samples a bandgap reference voltage to produce a sampled bandgap reference voltage. The sample-and-hold circuit includes a voltage divider to divide the sampled bandgap reference into an at least one divided reference voltage.

### TECHNICAL FIELD

The present application relates generally to circuits for sampling bandgap reference voltages and more specifically to a multi-reference-voltage sampled-bandgap system.

### BACKGROUND

Stable reference voltages such as generated by bandgap reference circuits are used in numerous integrated circuit applications including analog-to-digital converters and digital-to-analog converters. But the generation of stable and accurate reference voltages by a bandgap reference circuit typically consumes a substantial amount of power. To limit the power consumption, a sample-and-hold circuit may be used to sample a reference voltage generated by a bandgap reference circuit. The bandgap reference circuit may then be operated intermittently so as to reduce the power consumption. Each reference voltage produced by a bandgap reference circuit is thus sampled-and-held by a corresponding sample-and-hold circuit, whereupon the bandgap reference circuit may be cycled off until the sample-and-held reference voltages need to be refreshed. But as the number of reference voltages is increased, so is the number of corresponding sample-and-hold circuits. The semiconductor die space occupied by the sample-and-hold circuits and the corresponding power consumption thus increases linearly with the number of reference voltages.

### SUMMARY

In accordance with an aspect of the disclosure, a sample-and-hold circuit is provided that includes: a holding capacitor configured to be charged with a reference voltage; a differential amplifier coupled to the holding capacitor and configured to buffer the reference voltage into a sampled reference voltage; and a voltage divider coupled to the differential amplifier and configured to divide the sampled reference voltage into at least one divided reference voltage.

In accordance with another aspect of the disclosure, a method is provided that includes: sampling a reference voltage in a single-capacitor sample-and-hold circuit to produce a sampled reference voltage; and dividing the sampled reference voltage in a voltage divider to produce at least one divided reference voltage.

Finally, in accordance with yet another aspect of the disclosure, a multi-reference-voltage sampled-bandgap system is provided that includes: a bandgap reference circuit configured to generate a bandgap reference voltage; and a single-capacitor sample-and-hold circuit configured to sample the bandgap reference voltage to produce a sampled reference voltage, wherein the single-capacitor sample-and-hold circuit includes a voltage divider configured to divide the sampled reference voltage into an at least one divided reference voltage.

These and other advantageous features may be better appreciated through the following detailed description.

### BRIEF DESCRIPTION OF THE DRAWINGS

FIG. 1 illustrates a prior-art sample-and-hold circuit for a multi-reference-voltage sampled-bandgap system.

FIG. 2 illustrates a multi-reference-voltage sampled-bandgap system in accordance with an aspect of the disclosure.

FIG. 3 is a timing diagram for various signals in the multi-reference-voltage sampled-bandgap system of FIG. 2 in accordance with an aspect of the disclosure.

FIG. 4 illustrates a multi-reference-voltage sampled-bandgap system in accordance with an aspect of the disclosure.

FIG. 5 is a flowchart of a method of sampling a reference voltage in accordance with an aspect of the disclosure.

FIG. 6 illustrates some example electronic systems including a multi-reference-voltage sampled-bandgap system in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

Integrated circuit applications that require more than one reference voltage may include a multi-output bandgap reference circuit. But the generation of accurate and stable reference voltages by a multi-output bandgap reference circuit often consumes a substantial amount of power. To limit the power consumption, the multi-output bandgap reference circuit may be cycled on and off. In each cycle, the multi-output bandgap reference circuit is on for a relatively brief on-time and then switched off for a longer off-time. If a duty cycle for this cycling on-and-off is defined by a ratio of a sum of the on-time and the off-time divided by the on-time, the relatively brief on-time results in a large duty cycle such as four hundred. In this fashion, the power consumption from the multi-output bandgap reference circuit is advantageously reduced.

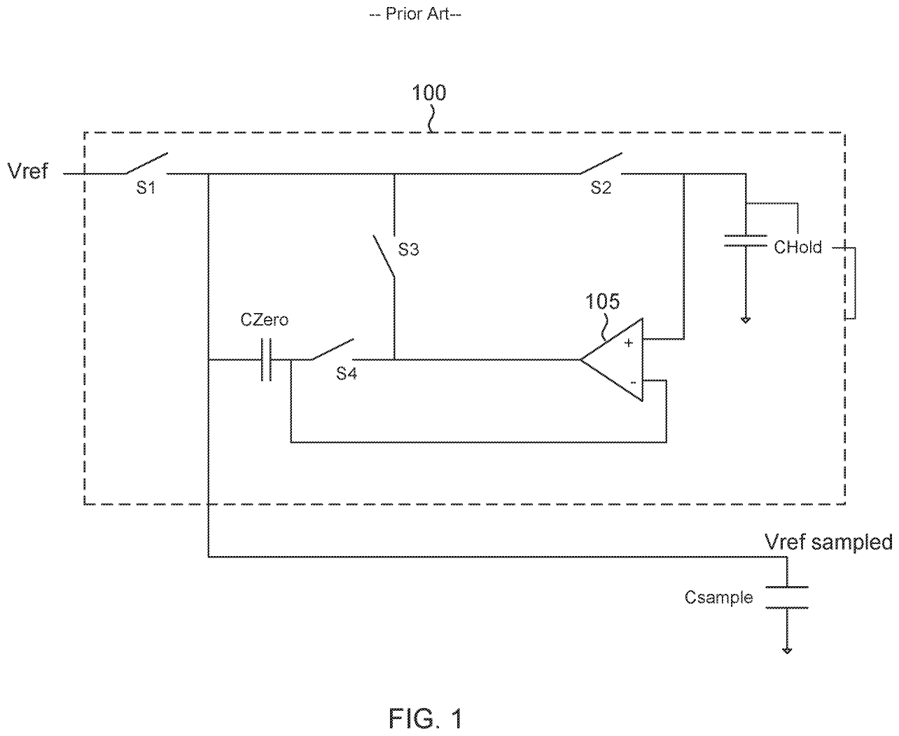

Since the multi-output bandgap reference circuit is switched on relatively infrequently, it is known for each reference voltage to be sampled and held by a corresponding sample-and-hold circuit. An example sample-and-hold circuit 100 is shown in FIG. 1. A bandgap reference voltage (Vref) from a multi-output bandgap reference circuit (not illustrated) passes through a switch S1 and a switch S2 to charge a capacitor Chold during a sampling time when both switches S1 and S2 are on. A differential amplifier 105 receive the voltage Vref at a non-inverting input. An output terminal of the differential amplifier 105 couples through a switch S4 that is closed during the sampling time to charge an offset-cancelling capacitor Czero with the offset voltage of the differential amplifier 105. The output terminal of the differential amplifier 105 also couples through a switch S3 to a node between switches S1 and S2. Switch S3 is open during the sampling time. An inverting terminal of the differential amplifier 105 couples to a node between the switch S4 and the capacitor Czero. During a hold time, switches S1, S2 and S4 are opened and the switch S3 is closed. The sampled reference voltage Vref is thus imposed on both sides of the opened switch S2 to prevent leakage from the capacitor Chold through the opened switch S2. A node between the switch S1 and the capacitor Czero couples to an output capacitor Csample to store the sampled reference voltage (Vref sampled).

There are several drawbacks from the use of sample-and-hold circuit 100. In particular, each reference voltage needs to be sampled-and-held by a corresponding sample-and-hold circuit 100. For example, the four reference voltages produced by a four-output bandgap reference circuit would be sampled-and-held by four corresponding sample-and-hold circuits 100. More generally, an N-output bandgap reference circuit would couple to N sample-and-hold circuits 100, where N is a plural positive integer. The semiconductor die area occupied by the sample-and-hold circuits 100 as well as their power consumption will thus linearly scale with the number N of reference voltages. The semiconductor die area occupied by each sample-and-hold circuit 100 is exacerbated by the use of two relatively large capacitors (Chold and Czero). Moreover, the sampling of relatively low reference voltages may be difficult because of the drift of the sampled reference voltage caused by the offset of the differential amplifier 105.

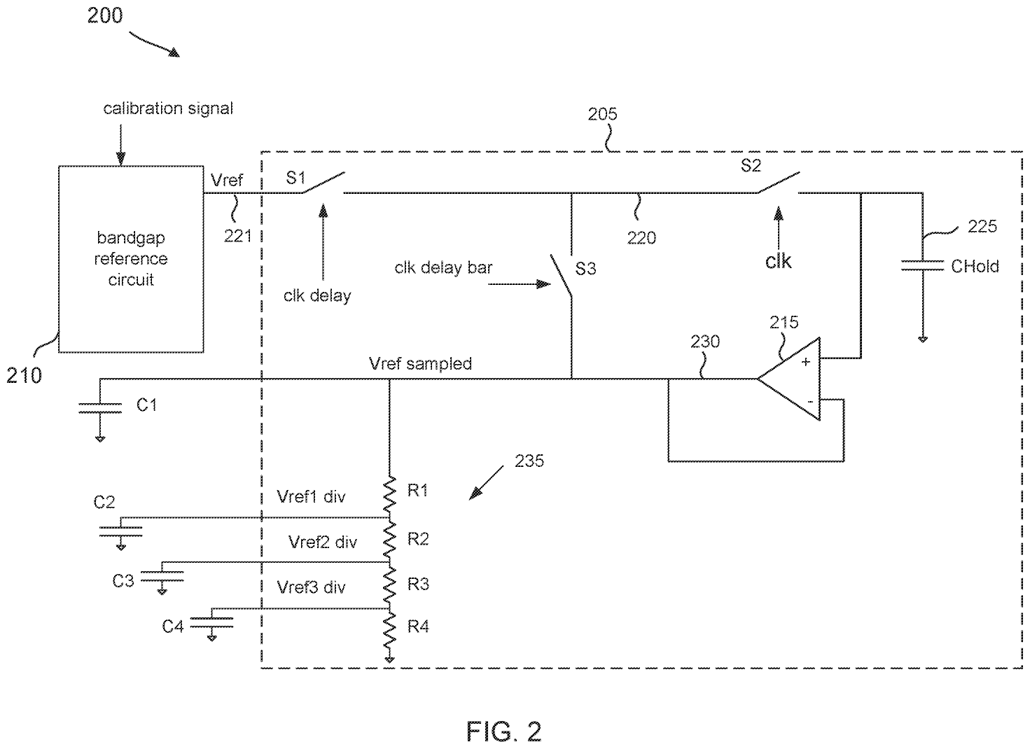

To address these issues, a single-capacitor sample-and-hold circuit is disclosed that samples-and-holds a reference voltage from a bandgap reference circuit. The single-capacitor sample-and-hold circuit includes a differential amplifier that buffers the reference voltage into a sampled reference voltage. The single-capacitor sample-and-hold circuit also includes a voltage divider that divides the sampled reference voltage to form divided reference voltages. The voltage divider may be formed by a serial chain of resistors. An example system 200 including a single-capacitor sample-and-hold circuit 205 and a single-output bandgap reference circuit 210 is shown in FIG. 2. To save power, single-output bandgap reference circuit 210 generates a reference voltage Vref only during a relatively brief on-time. For example, if a duty cycle for this cycling on-and-off of circuit 210 is defined by the ratio of a sum of the circuit's on-time and off-time divided by the on-time, the relatively brief on-time results in a large duty cycle such as four hundred, although it will be appreciated that other duty cycles may be used for system 200. During the on-time, the sample-and-hold circuit 205 samples the reference voltage Vref during a sampling period or time in which a switch S1 and a switch S2 coupled in series between an input terminal 221 and a terminal 225 of a holding capacitor Chold are both closed. Input terminal 221 couples to an output terminal of the bandgap reference circuit 210 to receive the reference voltage. Switch S2 opens responsive to an assertion of a clock (clk) signal. Switch S1 opens approximately simultaneously with switch S2 but with a slight delay for stability purposes. Thus, switch S1 opens in response to an assertion of a delayed clock (clk delay) signal that is slightly delayed with respect to the clock signal. During the sampling period when both switches S1 and S2 are closed, the capacitor Chold is charged to the reference voltage.

A differential amplifier 215 has a non-inverting input terminal that couples to the terminal 225 of the capacitor Chold. An inverting input terminal of the differential amplifier 215 couples to an output terminal 230 of the differential amplifier 215. Feedback through the differential amplifier 215 thus forces a voltage of the output terminal 230 to equal a buffered version (Vref sampled) of the reference voltage. This buffered version of the reference voltage is also denoted herein as a sampled reference voltage. Note that no equivalent of the capacitor Czero is needed to address the offset voltage of the differential amplifier 215 as will be further explained herein.

A holding period follows the sampling period in which both the clock signal and the delayed clock signal are asserted, which forces switches S1 and S2 open. A switch S3 couples between the output terminal 230 and a node 220 between switches S1 and S2. A complementary version of the delayed clock signal (clk delay bar) controls switch S3 such that switch S3 is open during the sampling period and closed during the holding period. With switch S3 closed during the holding period, both node 220 and the terminal 225 are charged to the reference voltage to prevent leakage current from flowing through opened switch S2 during the holding period.

The sampled reference voltage (Vref sampled) charges a first capacitor C1 that couples between the output terminal 230 and ground. To produce additional reference voltages, a voltage divider 235 couples between the output terminal 230 and ground. Voltage divider 235 is formed by a serial chain of resistors. Depending upon how many resistors are in the voltage divider 235 determines how many additional reference voltages may be generated. In voltage divider 235, there are four resistors R1, R2, R3, and R4 such that three divided reference voltages may be produced. A second capacitor C2 couples between ground and a node between resistors R1 and R2 to be charged by a first divided reference voltage (Vref1 div). Similarly, a third capacitor C3 couples between ground and a node between resistors R2 and R3 to be charged by a second divided reference voltage (Vref2 div). Finally, a fourth capacitor C4 couples between ground and a node between resistors R3 and R4 to be charged by a third divided reference voltage. More generally, a voltage divider with N resistors can produce (N−1) divided reference voltages, where N is a plural positive integer.

The resistances of the resistors in the voltage divider 235 determine the values of the divided reference voltages. Resistors of the same or different values can be used in various implementations. The exemplary implementation shown in FIG. 2 has 4 resistors R1-R4 and 4 capacitors C1-C4. However, other implementations can include more (e.g., 5, 6, etc.) or fewer (e.g., 3, 2) resistors and capacitors. Regardless of the particular resistances used, the first divided reference voltage is greater than the second divided reference voltage, and the second divided reference voltage is greater than the third divided reference voltage. For example, in one implementation in which the reference voltage equals 1.2V, the first divided reference voltage may equal 0.9V, the second divided reference voltage may equal 0.6V, and the third divided reference voltage may equal 0.3V. However, it will be appreciated that such voltages are exemplary and different reference voltages may be generated in alternative implementations. As compared to sample-and-hold circuit 100, sample-and-hold circuit 205 may more accurately produce relatively small reference voltages such as the 0.3V just discussed. In contrast, the offset of the differential amplifier 105 in the sample-and-hold circuit 100 may result in an inaccurate value for such a relatively small reference voltage.

To address the offset of the differential amplifier 215, the bandgap reference circuit 210 may be calibrated responsive to a calibration signal such as at manufacture of system 200. For example, due to linearity of the voltage divider 235, just one of the sampled reference voltage and the divided reference voltages may be tested during the calibration procedure to determine an error between the desired voltage and the actual voltage. Based upon this error, a calibration signal causes the bandgap reference circuit 210 to adjust the reference voltage (Vref) such that the sampled reference voltage (Vref sampled) and the divided reference voltage (Vref1 div through Vref3 div) equal the desired values. Since it is known to calibrate bandgap reference circuits, the calibration circuitry within the bandgap reference circuit 210 that responds to the calibration signal will not be discussed in detail herein. Note, however, that such known calibration techniques are not used in association with a sample-and-hold circuit such as sample-and-hold circuit 100 due to the use of the Czero capacitor.

Sample-and-hold circuit 205 has multiple advantages over the use of sample-and-hold circuit 100. For example, sample-and-hold circuit 205 may produce any number of divided reference voltages depending upon the implementation of voltage divider 235. In contrast, sample-and-hold circuit 100 is duplicated for each additional reference voltage. Moreover, sample-and-hold circuit 235 uses just one holding capacitor Chold whereas each sample-and-hold circuit 100 also uses the Czero capacitor. Each duplication of the sample-and-hold circuit 100 thus increases the occupied semiconductor die space and increases the power consumption. System 200 therefore saves substantial power and is considerably more compact as compared to the use of traditional sample-and-hold circuits 100.

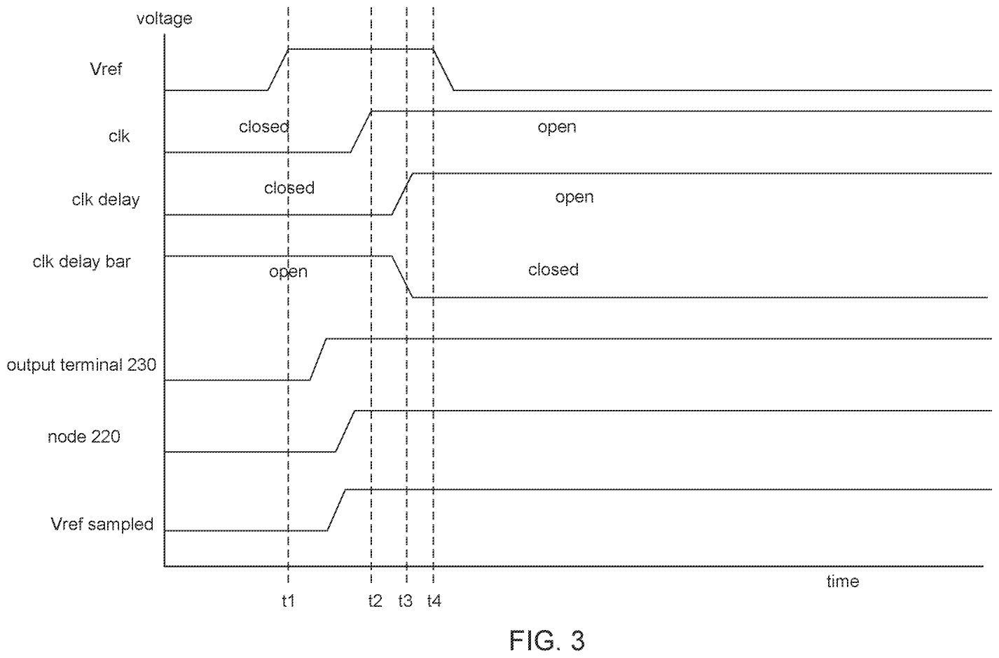

A timing diagram for various signals within system 200 is shown in FIG. 3. As discussed previously, bandgap reference circuit 210 is cycled on only for a relatively brief period on-time that in FIG. 3 exists from a time t1 to a time t4. Prior to time t1, both switches S1 and S2 are closed such that the sampling of the reference voltage may begin at time t1. The output terminal 230 of the capacitor Chold is thus charged to the reference voltage shortly after time t1. Following a propagation delay through the differential amplifier 205 after the charging of the output terminal 230, the node 220 and the sampled reference voltage (Vref sampled) are both charged. At a time t2, the clock signal clk is asserted to open switch S2. A short delay later at a time t3, the delayed clock signal (clk delay) is asserted to open switch S3. At the same time t3, the complementary version of the delayed clock signal (clk delay bar) is de-asserted to close switch S3. Finally, the on-time of the bandgap reference circuit 200 ends at time t4 so that the reference voltage falls to ground.

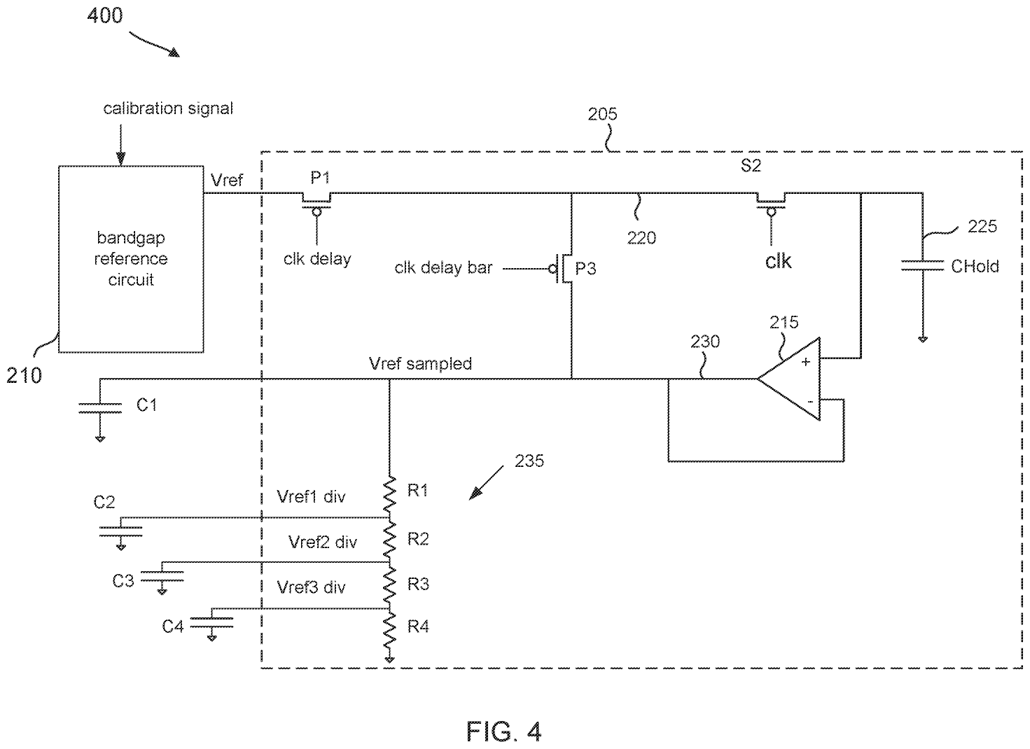

With regard to the control of switches S1, S2, and S3, the timing diagram of FIG. 3 assumes that the clock signals are active-low such that their respective switches close when their clock signals are discharged and open when their clock signals are charged. In that regard, switches S1, S2, and S3 may each be implemented using a p-type metal-oxide semiconductor (PMOS) transistor as shown for a system 400 of FIG. 4. However, it will be appreciated that in alternative implementations, each of switches S1, S2, and S3 may be constructed so as to close when their respective clock signals are charged as compared to being discharged. System 400 is as discussed for system 200 except that switches S1, S2, and S3 are implemented using PMOS transistors P1, P2, and P3, respectively. The delayed clock signal (clk delay) drives the gate of transistor P1. Similarly, the clock signal (clk) drives the gate of transistor P2. Finally, the complementary version of the delayed clock signal (clk delay bar) drives the gate of transistor P3. In an alternative implementation, the switches S1, S2, and D3 can be implemented using n-type metal-oxide semiconductor (NMOS) transistors.

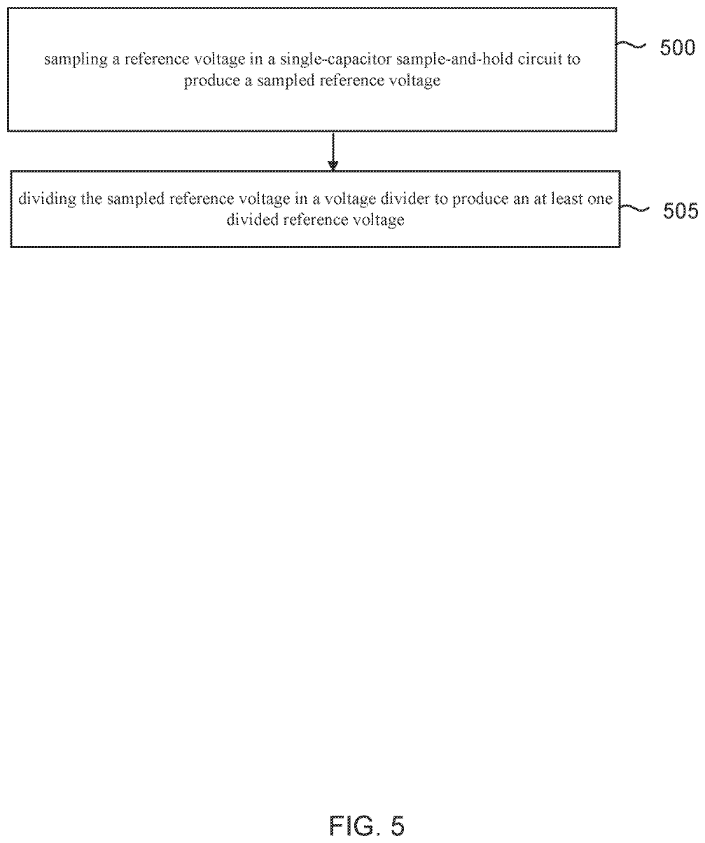

A method of operation of system 200 will now be discussed with respect to the flowchart of FIG. 5. The method includes an act 500 of sampling a reference voltage in a single-capacitor sample-and-hold circuit to produce a sampled reference voltage. The production of the sampled reference voltage (Vref sampled) by the sample-and-hold circuit 205 is an example of act 500. In addition, the method include an act 505 of dividing the sampled reference voltage in a voltage divider to produce an at least one divided reference voltage. The division by voltage divider 230 to produce any of the divided voltages (Vref1 div, Vref2 div, or Vref3 div) is an example of act 505.

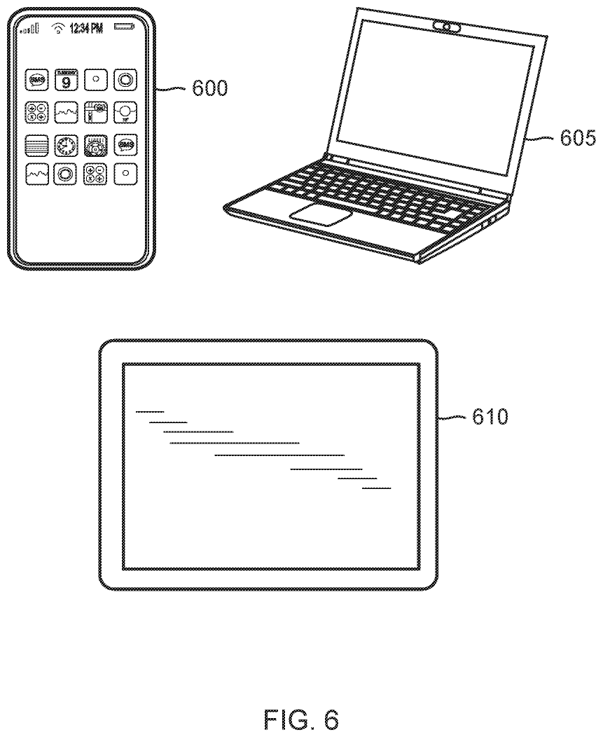

A multi-reference-voltage sampled-bandgap system such as system 200 disclosed herein may be incorporated in a wide variety of electronic systems. For example, as shown in FIG. 6, a cellular telephone 600, a laptop computer 605, and a tablet PC 610 may each include a multi-reference-voltage sampled-bandgap system in accordance with the disclosure. Other exemplary electronic systems such as a music player, a video player, a communication device, and a personal computer may also be configured with a multi-reference-voltage sampled-bandgap system constructed in accordance with the disclosure.

The disclosure will now be summarized through the following example clauses:

Clause 1. A sample-and-hold circuit, comprising:
a holding capacitor configured to be charged with a reference voltage;
a differential amplifier coupled to the holding capacitor and configured to buffer the reference voltage into a sampled reference voltage; and
a voltage divider coupled to the differential amplifier and configured to divide the sampled reference voltage into at least one divided reference voltage.
   Clause 2. The sample-and-hold circuit of clause 1, further comprising:
an input terminal;
a first switch coupled to the input terminal; and
a second switch coupled in series between the first switch and the holding capacitor.
   Clause 3. The sample-and-hold circuit of clause 2, further comprising:
a third switch coupled between an output terminal of the differential amplifier and a node between the first switch and the second switch.
   Clause 4. The sample-and-hold circuit of any of clauses 1-3, wherein a non-inverting input terminal of the differential amplifier couples to the holding capacitor, and wherein an inverting terminal of the differential amplifier couples to an output terminal of the differential amplifier.
   Clause 5. The sample-and-hold circuit of any of clauses 2-3, wherein the sample-and-hold circuit is incorporated into a multi-reference-voltage sampled-bandgap system including a bandgap reference circuit having an output terminal coupled to the input terminal, and wherein the reference voltage is a bandgap reference voltage.
   Clause 6. The sample-and-hold circuit of clause 5, wherein the bandgap reference circuit is a single-output bandgap reference circuit.
   Clause 7. The sample-and-hold circuit of any of clauses 5-6, wherein the multi-reference-voltage sampled-bandgap system includes a first capacitor coupled to an output terminal of the differential amplifier.
   Clause 8. The sample-and-hold circuit of clause 7, wherein the voltage divider includes a first resistor coupled to a second resistor, and wherein the multi-reference-voltage sampled-bandgap system further includes a second capacitor coupled to a node between the first resistor and the second resistor.
   Clause 9. The sample-and-hold circuit of clause 8, wherein the voltage divider includes a third resistor coupled to the second resistor, and wherein the multi-reference-voltage sampled-bandgap system further includes a third capacitor coupled to a node between the second resistor and the third resistor.
   Clause 10. The sample-and-hold circuit of clause 9, wherein the voltage divider includes a fourth resistor coupled between the third resistor and ground, and wherein the multi-reference-voltage sampled-bandgap system further includes a fourth capacitor coupled to a node between the third resistor and the fourth resistor.
   Clause 11. The sample-and-hold circuit of clause 5, wherein the bandgap reference circuit is configured to adjust the reference voltage responsive to a calibration signal.
   Clause 12. A method, comprising:
sampling a reference voltage in a single-capacitor sample-and-hold circuit to produce a sampled reference voltage; and
dividing the sampled reference voltage in a voltage divider to produce an at least one divided reference voltage.
   Clause 13. The method of clause 12, further comprising:
generating the reference voltage in a bandgap reference circuit.
   Clause 14. The method of clause 13, wherein generating the reference voltage comprises generating the reference voltage during an on-time of the bandgap reference circuit, and wherein the on-time is followed by an off-time of the bandgap reference circuit.
   Clause 15. The method of clause 14, wherein sampling the reference voltage in the single-capacitor sample-and-hold circuit comprises coupling a holding capacitor through a pair of switches to an output terminal of the bandgap reference circuit during the on-time of the bandgap reference circuit.
   Clause 16. The method of clause 14, wherein the on-time is shorter than the off-time.
   Clause 17. A multi-reference-voltage sampled-bandgap system, comprising:
a bandgap reference circuit configured to generate a bandgap reference voltage; and
a single-capacitor sample-and-hold circuit configured to sample the bandgap reference voltage to produce a sampled reference voltage, wherein the single-capacitor sample-and-hold circuit includes a voltage divider configured to divide the sampled reference voltage into an at least one divided reference voltage.
   Clause 18. The multi-reference-voltage sampled-bandgap system of clause 17, wherein the at least one divided reference voltage comprises a plurality of divided reference voltages.
   Clause 19. The multi-reference-voltage sampled-bandgap system of any of clauses 17-18, wherein the single-capacitor sample-and-hold circuit comprises:
a single holding capacitor;
an input terminal coupled to an output terminal of the bandgap reference circuit;
a first switch coupled to the input terminal;
a second switch coupled between the first switch and the single holding capacitor;
a differential amplifier having a non-inverting input coupled to the single holding capacitor and having an inverting input coupled to an output terminal of the differential amplifier; and
a third switch coupled between the output terminal of the differential amplifier and a node between the first switch and the second switch.
   Clause 20. The multi-reference-voltage sampled-bandgap system of clause 19, wherein the first switch comprises a first p-type metal-oxide semiconductor (PMOS) transistor, the second switch comprises a second PMOS transistor, and the third switch comprise a third PMOS transistor.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A sample-and-hold circuit, comprising:
a holding capacitor configured to be charged with a reference voltage;
a differential amplifier coupled to the holding capacitor and configured to buffer the reference voltage into a sampled reference voltage; and
a voltage divider coupled to the differential amplifier and configured to divide the sampled reference voltage into at least one divided reference voltage.

2. The sample-and-hold circuit of claim 1, further comprising:
an input terminal;
a first switch coupled to the input terminal; and
a second switch coupled in series between the first switch and the holding capacitor.

3. The sample-and-hold circuit of claim 2, further comprising:
a third switch coupled between an output terminal of the differential amplifier and a node between the first switch and the second switch.

4. The sample-and-hold circuit of claim 1, wherein a non-inverting input terminal of the differential amplifier couples to the holding capacitor, and wherein an inverting terminal of the differential amplifier couples to an output terminal of the differential amplifier.

5. The sample-and-hold circuit of claim 2, wherein the sample-and-hold circuit is incorporated into a multi-reference-voltage sampled-bandgap system including a bandgap reference circuit having an output terminal coupled to the input terminal, and wherein the reference voltage is a bandgap reference voltage.

6. The sample-and-hold circuit of claim 5, wherein the bandgap reference circuit is a single-output bandgap reference circuit.

7. The sample-and-hold circuit of claim 5, wherein the multi-reference-voltage sampled-bandgap system includes a first capacitor coupled to an output terminal of the differential amplifier.

8. The sample-and-hold circuit of claim 7, wherein the voltage divider includes a first resistor coupled to a second resistor, and wherein the multi-reference-voltage sampled-bandgap system further includes a second capacitor coupled to a node between the first resistor and the second resistor.

9. The sample-and-hold circuit of claim 8, wherein the voltage divider includes a third resistor coupled to the second resistor, and wherein the multi-reference-voltage sampled-bandgap system further includes a third capacitor coupled to a node between the second resistor and the third resistor.

10. The sample-and-hold circuit of claim 9, wherein the voltage divider includes a fourth resistor coupled between the third resistor and ground, and wherein the multi-reference-voltage sampled-bandgap system further includes a fourth capacitor coupled to a node between the third resistor and the fourth resistor.

11. The sample-and-hold circuit of claim 5, wherein the bandgap reference circuit is configured to adjust the reference voltage responsive to a calibration signal.

12. A method, comprising:
sampling a reference voltage in a single-capacitor sample-and-hold circuit to produce a sampled reference voltage; and
dividing the sampled reference voltage in a voltage divider to produce an at least one divided reference voltage.

13. The method of claim 12, further comprising:
generating the reference voltage in a bandgap reference circuit.

14. The method of claim 13, wherein generating the reference voltage comprises generating the reference voltage during an on-time of the bandgap reference circuit, and wherein the on-time is followed by an off-time of the bandgap reference circuit.

15. The method of claim 14, wherein sampling the reference voltage in the single-capacitor sample-and-hold circuit comprises coupling a holding capacitor through a pair of switches to an output terminal of the bandgap reference circuit during the on-time of the bandgap reference circuit.

16. The method of claim 14, wherein the on-time is shorter than the off-time.

17. A multi-reference-voltage sampled-bandgap system, comprising:
a bandgap reference circuit configured to generate a bandgap reference voltage; and
a single-capacitor sample-and-hold circuit configured to sample the bandgap reference voltage to produce a sampled reference voltage, wherein the single-capacitor sample-and-hold circuit includes a voltage divider configured to divide the sampled reference voltage into an at least one divided reference voltage.

18. The multi-reference-voltage sampled-bandgap system of claim 17, wherein the at least one divided reference voltage comprises a plurality of divided reference voltages.

19. The multi-reference-voltage sampled-bandgap system of claim 17, wherein the single-capacitor sample-and-hold circuit comprises:
a single holding capacitor;
an input terminal coupled to an output terminal of the bandgap reference circuit;
a first switch coupled to the input terminal;
a second switch coupled between the first switch and the single holding capacitor;
a differential amplifier having a non-inverting input coupled to the single holding capacitor and having an inverting input coupled to an output terminal of the differential amplifier; and
a third switch coupled between the output terminal of the differential amplifier and a node between the first switch and the second switch.

20. The multi-reference-voltage sampled-bandgap system of claim 19, wherein the first switch comprises a first p-type metal-oxide semiconductor (PMOS) transistor, the second switch comprises a second PMOS transistor, and the third switch comprise a third PMOS transistor.
